(19) United States
(12) Patent Application Publication
(10) Pub. No.: US 2026/0316564 A1
(43) Pub. Date: Oct. 15, 2026

(54) BACKLIGHT MODULE AND DISPLAY DEVICE

(71) Applicants: Beijing BOE Display Technology Co., Ltd., Beijing (CN); BOE Technology Group Co., Ltd., Beijing (CN); Beijing BOE Technology Development Co., Ltd., Beijing (CN)

(72) Inventors: Fengping Wang, Beijing (CN); Rui Han, Beijing (CN); Dong Cui, Beijing (CN); Wenyang Li, Beijing (CN); Yue Zhai, Beijing (CN); Zhipeng Zhang, Beijing (CN); Weining Chi, Beijing (CN); Shouyang Leng, Beijing (CN); Yinong Tian, Beijing (CN); Mei You, Beijing (CN); Xiaoqiao Dong, Beijing (CN); Chunhua Wang, Beijing (CN); Daekeun Yoon, Beijing (CN); Qing Ma, Beijing (CN); Biqi Li, Beijing (CN)

(73) Assignees: Beijing BOE Display Technology Co., Ltd., Beijing (CN); BOE Technology Group Co., Ltd., Beijing (CN); Beijing BOE Technology Development Co., Ltd., Beijing (CN)

(21) Appl. No.: 19/485,791

(22) PCT Filed: Apr. 18, 2024
(86) PCT No.: PCT/CN2024/088649

§ 371 Date: Nov. 19, 2025

(30) Foreign Application Priority Data
May 22, 2023 (CN) 202310577521.2

(51) Int. Cl. B60K 35/22; B60K 35/215; B60K 35/81; H10H 29/855

(52) U.S. Cl. CPC B60K 35/22; B60K 35/215; B60K 35/81; H10H 29/8552; B60K 2360/332; B60K 2360/42

(57) ABSTRACT

Provided are a backlight module and a display device. The backlight module includes: a base plate; a light board disposed on a side of the base plate, configured to provide a light source; a diffusion plate stacked on a side of the light board facing away from the base plate; an optical film stacked on a side of the diffusion plate facing away from the base plate; and a first through hole penetrating through the base plate, the light board, the diffusion plate, and the optical film along a normal direction of the base plate.

### CROSS-REFERENCE TO RELATED APPLICATIONS

The present application claims priority to Chinese patent application No. 202310577521.2, entitled “BACKLIGHT MODULE AND DISPLAY DEVICE”, filed on May 22, 2023 before the China National Intellectual Property Administration, which is incorporated herein in its entirety by reference.

### TECHNICAL FIELD

The present disclosure relates to the field of display technologies, and in particular, to a backlight module and a display device.

### BACKGROUND

With the development of the times and the advancement of technology, display screen technology has also been rapidly evolving. Traditional backlight modules can no longer meet the requirements of in-vehicle displays.

### SUMMARY

The present disclosure provides a backlight module, including:
a base plate;
a light board disposed on a side of the base plate, configured to provide a light source;
a diffusion plate stacked on a side of the light board facing away from the base plate;
an optical film stacked on a side of the diffusion plate facing away from the base plate; and
a first through hole penetrating through the base plate, the light board, the diffusion plate, and the optical film along a normal direction of the base plate.

In some embodiments, the first through hole includes:
a first sub-hole close to the base plate and a second sub-hole facing away from the base plate, wherein an orthographic projection of the first sub-hole on the base plate is greater than an orthographic projection of the second sub-hole on the base plate in terms of dimensions, and the orthographic projection of the first sub-hole on the base plate covers the orthographic projection of the second sub-hole on the base plate.

In some embodiments, the backlight module further includes:
a hole wall arranged around the first through hole and connected to an edge of the base plate adjacent to the first through hole, wherein the light board, the diffusion plate, and the optical film are located on a side of the hole wall facing away from the first through hole.

In some embodiments, the backlight module further includes:
a first light-shielding tape adhered to a side of the hole wall facing away from the base plate, wherein an orthographic projection of the first light-shielding tape on the base plate is within an orthographic projection of the hole wall on the base plate, and the first light-shielding tape is a closed structure surrounding the first through hole.

In some embodiments, the backlight module further includes:
a camera embedded in the first through hole from a side of the base plate facing away from the light board, wherein the camera includes a light-incident surface and a fixed surface arranged opposite to each other, the light-incident surface is arranged facing away from the base plate;
a control board fixedly connected to the fixed surface, including at least one of: a device area, a blank area and a hole area, wherein components on a side of the control board close to the fixed surface are all located in the device area, a second through hole penetrating through the control board is provided in the hole area; and
a fixing structure disposed on a side of the base plate close to the control board, including at least one of: a first boss, a protruding first screw hole, and a protruding first stud;
wherein the first boss is configured for adhesive fixation with the blank area, the first screw hole is configured for fixation with the second through hole via a screw, and the first stud is configured for fixation with the second through hole via a nut.

In some embodiments, the light board includes:
a substrate;
a plurality of light-emitting devices spaced apart and located on a side of the substrate facing away from the base plate; and
a driving device located on a side of the substrate close to the base plate;
wherein a surface of the base plate close to the light board is provided with at least one of a first groove and a thermal conductive adhesive, wherein the first groove is configured to partially or completely penetrate the base plate, and form an avoidance space for the driving device, an insulating tape is attached to a surface of the first groove close to the driving device; the thermal conductive adhesive is configured to adhere the light board to the base plate.

In some embodiments, the light board further includes:
a reflective structure disposed on the side of the substrate facing away from the base plate and located around the light-emitting devices, the reflective structure is configured to reflect light incident from the diffusion plate back to the diffusion plate;
wherein the reflective structure includes at least one of: reflective oil, a reflective sheet, a reflector cup, and a reflective housing.

In some embodiments, the light board includes a plurality of light-emitting devices arranged in a periodic pattern, a gap exists between the light board and the diffusion plate, the gap is proportional to an arrangement period of the light-emitting devices, with a proportional coefficient greater than or equal to 0.3 and less than or equal to 1.2.

In some embodiments, the backlight module further includes:
a side plate connected to an edge of the base plate facing away from the first through hole and located on a periphery of the light board, the diffusion plate, and the optical film, wherein the side plate includes a first side plate; and
a first frame body arranged on a side of the first side plate facing away from the first through hole, wherein a surface of the first side plate facing away from the first through hole includes a covered area and an exposed area, the covered area is covered by the first frame body, the first frame body is adhesively fixed to the covered area, a second groove is provided in the exposed area, and a groove wall of the second groove includes a surface of the first frame body close to the exposed area.

In some embodiments, the backlight module further includes:
a side plate connected to an edge of the base plate facing away from the first through hole and located on a periphery of the light board, the diffusion plate, and the optical film, wherein the side plate includes a second side plate;
a second frame body arranged on a side of the second side plate facing away from the first through hole, wherein the second frame body is snap-fitted to the second side plate; and
a first rubber pad located on a side of the second frame body facing away from the second side plate, wherein the first rubber pad includes a hollowed-out structure a central area of the first rubber pad.

In some embodiments, an edge of the diffusion plate is provided with a first lug, and the backlight module further includes:
a side plate connected to an edge of the base plate facing away from the first through hole and located on a periphery of the light board, the diffusion plate, and the optical film, wherein a surface of the side plate close to the first through hole is provided with a third groove, the third groove is configured to position the first lug;
at least one second rubber pad disposed between the side plate and the diffusion plate, located on at least three sides of the diffusion plate, wherein the second rubber pad and the diffusion plate are in an interference fit; and
a first adhesive layer adhered between the diffusion plate and the side plate.

In some embodiments, an edge of the optical film is provided with a first notch and a second lug, the first notch and the second lug are arranged on opposite edges of the optical film respectively, and the backlight module further includes:
a side plate connected to an edge of the base plate facing away from the first through hole and located on a periphery of the light board, the diffusion plate, and the optical film, wherein a surface of the side plate close to the first through hole is provided with a second boss and a fourth groove, the second boss is configured to position the first notch, and the fourth groove is configured to position the second lug; and
a second adhesive layer including a plurality of adhesive portions, wherein the plurality of adhesive portions are adhered between different optical films and the side plate.

In some embodiments, the backlight module further includes:
a privacy screen protector located on a side of the optical film facing away from the diffusion plate, wherein an orthographic projection of the privacy screen protector on the diffusion plate partially covers the diffusion plate, and an orthographic projection of the privacy screen protector on the base plate does not overlap with an orthographic projection of the first through hole on the base plate.

In some embodiments, an edge of the privacy screen protector is provided with a second notch and a third lug, the second notch and the third lug are located on two adjacent edges of the optical film respectively; and the backlight module further includes:
a side plate connected to an edge of the base plate facing away from the first through hole and located on a periphery of the light board, the diffusion plate, and the optical film, wherein a surface of the side plate close to the first through hole is provided with a third boss and a fifth groove, the third boss is configured to position the second notch, and the fifth groove is configured to position the third lug;
a third frame body arranged on a side of the side plate and the privacy screen protector facing away from the base plate, third frame body includes a privacy frame body and a non-privacy frame body, wherein the privacy frame body is adjacent to the privacy screen protector;
a third adhesive layer adhered between the privacy screen protector and the privacy frame body; and
a second light-shielding tape adhered to a surface of the non-privacy frame body close to the optical film.

The present disclosure provides a display device, including:
a display panel including an active display area; and
any backlight module described above, located on a side of the display panel facing away from a display surface and configured to provide a backlight source to the display panel.

In some embodiments, the active display area includes a plurality of sub-display areas, and the display device further includes:
a privacy panel disposed between the display panel and the backlight module, wherein the privacy panel includes a privacy area, and the privacy area is provided with a driving structure and functional particles, the driving structure is configured to establish an electric field for driving the functional particles to move, allowing a target sub-display area to be in a privacy state or a sharing state, the target sub-display area includes one or more of the sub-display areas.

In some embodiments, the display device further includes a plurality of alignment mark groups spaced apart, each alignment mark group includes:
a first alignment mark located in a border area on the display panel, the border area being located on at least one side of the active display area; and
a second alignment mark located on the privacy panel, wherein an orthographic projection of the second alignment mark on the display panel at least partially overlaps with the first alignment mark.

In some embodiments, the display device further includes:
a first chip-on-film with a first end bonded to the display panel and a second end bent to a side of the backlight module facing away from the display panel; and
a second chip-on-film with a first end bonded to the privacy panel and a second end bent to the side of the backlight module facing away from the display panel;
wherein the first chip-on-film and the second chip-on-film are arranged near opposite edges of the display device, respectively.

In some embodiments, the display device further includes:
a first drive chip connected to the first chip-on-film and located on a side of the first chip-on-film close to the backlight module; and
a second drive chip connected to the second chip-on-film and located on a side of the second chip-on-film close to the backlight module;
wherein an electromagnetic shielding tape is attached to a side of the first chip-on-film facing away from the first drive chip and a side of the second chip-on-film facing away from the second drive chip.

In some embodiments, the display device further includes:
a display circuit board connected to the second end of the first chip-on-film and arranged on a side of the backlight module facing away from the display panel, wherein the display circuit board includes a first display circuit board, a second display circuit board, and a first flexible circuit board connecting the first display circuit board and the second display circuit board, wherein an electromagnetic shielding tape is attached to a side of the first flexible circuit board facing away from the backlight module; and
a privacy circuit board connected to the second end of the second chip-on-film and arranged on the side of the backlight module facing away from the display panel, wherein the privacy circuit board includes a first privacy circuit board, a second privacy circuit board, and a second flexible circuit board connecting the first privacy circuit board and the second privacy circuit board, wherein an electromagnetic shielding tape is attached to a side of the second flexible circuit board facing away from the backlight module.

In some embodiments, the display circuit board is disposed close to the first chip-on-film, and the privacy circuit board is disposed close to the second chip-on-film;
in a normal direction of the display panel, the display circuit board and the privacy circuit board partially overlap, and a gap exists between the display circuit board and the privacy circuit board.

In some embodiments, the display device further includes:
a raising structure disposed on a side of the backlight module close to the display circuit board, configured to raise the display circuit board in the normal direction of the display panel;
the raising structure includes at least one of: a third rubber pad, a protruding second screw hole, and a protruding second stud, wherein the third rubber pad is adhesively fixed to the backlight module and the display circuit board, the second screw hole is configured for fixation with the display circuit board via a screw, and the second stud is configured for fixation with the display circuit board via a nut.

In some embodiments, the privacy circuit board includes: a first exposed metal area close to the backlight module, and a second exposed metal area facing away from the backlight module, the first exposed metal area is connected to the backlight module via a conductive double-sided tape, the second exposed metal area is disposed near an edge of the privacy circuit board, and the second exposed metal area is connected to the backlight module via a single-sided conductive tape;
the display circuit board includes:
a third through hole for the screw or stud to pass through, wherein a hole wall of the third through hole includes a third exposed metal area; and
a fourth exposed metal area facing away from the backlight module, disposed near an edge of the display circuit board, wherein the fourth exposed metal area is connected to the backlight module via a single-sided conductive tape.

In some embodiments, the active display area includes a first display partition and a second display partition, the first display circuit board is configured to drive the first display partition, and the second display circuit board is configured to drive the second display partition;
the light board includes a first light board and a second light board spliced together, the first light board is configured to provide a light source for the first display partition, and the second light board is configured to provide a light source for the second display partition;
wherein the first light board is connected to the first display circuit board, and the second light board is connected to the second display circuit board.

In some embodiments, the active display area includes a first sub-display area, and the display panel further includes: a first light-transmitting area, and a first light-shielding area arranged on at least one side of the first light-transmitting area, the first sub-display area is arranged on at least one side of the first light-shielding area;
wherein an orthographic projection of the first through hole on the display panel at least partially overlaps with the first light-transmitting area.

In some embodiments, the active display area includes a second sub-display area, and the display device further includes:
a cover plate disposed close to a light-emitting surface of the display panel; and
vibration exciters located on a side of the cover plate close to the display panel, symmetrically disposed on opposite sides of the second sub-display area and near edges of the cover plate.

In some embodiments, the backlight module further includes:
a side plate connected to an edge of the base plate facing away from the first through hole and located on a periphery of the light board, the diffusion plate, and the optical film;
the display device further includes:
a first chip-on-film bonded to the display panel;
a second chip-on-film bonded to the privacy panel; and
an adhesive structure disposed between the side plate and the cover plate, including at least one of:
a first double-sided tape located between adjacent first chips-on-film;
a second double-sided tape located between adjacent second chips-on-film, disposed on a side of the second sub-display area facing away from the first double-sided tape, and symmetrically arranged with the first double-sided tape on opposite sides of the second sub-display area;
a single-sided foam tape with its adhesive side facing the side plate, located between two adjacent second double-sided tapes;
a structural adhesive located between the first double-sided tape, the second double-sided tape, and the single-sided foam tape, with the same thickness as the first double-sided tape and the second double-sided tape; and
a plurality of mutually separated fourth bosses located on a surface of the side plate close to the cover plate, configured to limit a height between the cover plate and the side plate, wherein a single-sided tape is attached to a surface of the fourth bosses close to the cover plate.

In some embodiments, the display device further includes:
a cover plate disposed close to a light-emitting surface of the display panel; and
a light-transmitting ink located between the cover plate and the display panel, wherein an orthographic projection of the light-transmitting ink on the backlight module at least partially overlaps with the first through hole, and is configured to transmit light of a preset wavelength band, the preset wavelength band having no overlap or partial overlap with the visible light spectrum.

In some embodiments, the display panel further includes:
a border area located on at least one side of the active display area; and
an ambient light sensor located in the border area, configured to sense an intensity of ambient light.

The above description is only a general overview of solutions of the present disclosure. In order to learn technical means of the present disclosure more clearly and allow the technical means to be implemented based on the disclosure of the description, and in order to make the above and other objects, features and advantages of the present disclosure more apparent and understandable, specific embodiments of the present disclosure are illustrated below.

### BRIEF DESCRIPTION OF THE DRAWINGS

In order to describe technical solutions of the embodiments of the present disclosure or the related art more clearly, the accompanying drawings used in the illustration of the embodiments or the related art will be briefly introduced. Apparently, the accompanying drawings in the following explanation illustrate merely some embodiments of the present disclosure, and those skilled in the art may obtain other accompanying drawings based on these accompanying drawings without paying any creative effort. It should be noted that the scales in the drawings are for illustrative purposes only and do not represent the actual scales.

FIG. 1 is a schematic cross-sectional view of a backlight module;

FIG. 2 is a schematic structural diagram illustrating a top surface of a light board;

FIG. 3 is a schematic structural diagram illustrating a top surface of a base plate;

FIG. 4 is a schematic structural diagram illustrating a border area of a backlight module;

FIG. 5 is a schematic diagram of a positioning structure of a diffusion plate;

FIG. 6 is a schematic diagram of a positioning structure of an optical film;

FIG. 7 is a schematic diagram of a positioning structure of a privacy screen protector;

FIG. 8 schematically illustrates a cross-sectional view of a display module;

FIG. 9 schematically illustrates a planar structural diagram of a display panel;

FIG. 10 schematically illustrates a structural diagram of alignment mark groups;

FIG. 11 schematically illustrates a peripheral structural diagram of a display panel and a privacy panel;

FIG. 12 schematically illustrates a structural diagram of the border area of a display module;

FIG. 13 schematically illustrates a structural diagram of the bottom surface of a display module;

FIG. 14 schematically illustrates a structural diagram of the bottom surface of a base plate in a display module;

FIG. 15 schematically illustrates a positional diagram of vibration exciters in a display module;

FIG. 16 schematically illustrates a diagram of an adhesive solution between a cover plate and a back plate;

FIG. 17 schematically illustrates a positional diagram of an ambient light sensor in a display module;

FIG. 18 schematically illustrates a side view structural diagram of a display module; and

FIG. 19 schematically illustrates top and bottom surface diagrams of a display module.

### DETAILED DESCRIPTION

A clear and thorough description for solutions in the embodiments of the present disclosure will be given below in conjunction with the accompanying drawings in the embodiments of the present disclosure. Apparently, the described embodiments are a part of embodiments of the present disclosure, not all the embodiments. All other embodiments obtained, based on the embodiments in the present disclosure, by those skilled in the art without paying creative effort fall within the protection scope of the present disclosure.

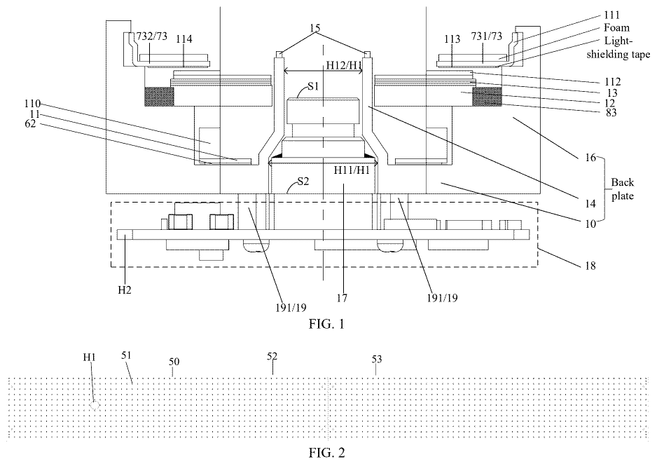

Referring to FIG. 1, a schematic structural diagram of a backlight module MD provided by the present disclosure is exemplarily shown. The backlight module MD includes: a base plate 10; a light board 11 disposed on one side of the base plate 10 and configured to provide a light source; a diffusion plate 12 stacked on a side of the light board 11 facing away from the base plate 10; an optical film 13 stacked on a side of the diffusion plate 12 facing away from the base plate 10; and a first through hole H1 that penetrates through the base plate 10, the light board 11, the diffusion plate 12, and the optical film 13 along a normal direction of the base plate 10.

Exemplarily, the diffusion plate 12 functions to increase a divergence angle of the incident light. For example, the material of the diffusion plate 12 may be polycarbonate, and the thickness of the diffusion plate 12 may range from 1 mm to 3 mm.

Exemplarily, the optical film 13 may include at least one of films stacked in sequence such as a diffusion sheet, a prism sheet, and a brightness enhancement film. The optical film 13 is configured to mix and brighten the incident light, among other functions. For example, the optical film 13 includes one diffusion sheet, two prism sheets, and one brightness enhancement film stacked in sequence.

The backlight module MD provided by the present disclosure is provided with a first through hole H1 penetrating through the base plate 10, the light board 11, the diffusion plate 12, and the optical film 13, so that a camera 17 can be integrated in the first through hole H1, thereby enabling camera functionality. For example, the backlight module MD can be applied to in-vehicle displays, eliminating the need for an independently installed camera 17, thus saving space inside the vehicle. The camera 17 can capture driver information in real time and provide safety prompts, enhancing driving safety.

The backlight module MD provided by the present disclosure employs a direct-lit backlight, enabling the backlight module MD to achieve local dimming functionality. This is beneficial for reducing the power consumption or improving brightness uniformity. Moreover, the direct-lit backlight does not require a light guide plate, facilitating the realization of a large-sized backlight module MD, further suitable for in-vehicle displays. The backlight module MD can also be used in consumer electronics products.

In some embodiments, as shown in FIG. 1, the first through hole H1 includes a first sub-hole H11 close to the base plate 10 and a second sub-hole H12 far from the base plate 10. The orthographic projection of the first sub-hole H11 on the base plate 10 is greater than the orthographic projection of the second sub-hole H12 on the base plate 10 in terms of size, and the orthographic projection of the first sub-hole H11 on the base plate 10 covers the orthographic projection of the second sub-hole H12 on the base plate 10.

Exemplarily, as shown in FIG. 1, the first through hole is a stepped hole composed of the first sub-hole H11 and the second sub-hole H12. For example, an outer diameter of the first sub-hole H11 is 10 mm, and the maximum outer diameter of the second sub-hole H12 is 7 mm.

In specific implementations, the orthographic projections of the first sub-hole H11 and the second sub-hole H12 on the base plate 10 may be in a shape of a circle, an ellipse, a square, or other polygons, and can also be irregular shapes. The specific shapes can be designed according to the shape of the camera 17, which is not limited in the present disclosure.

In some embodiments, as shown in FIG. 1, the backlight module MD further includes: a hole wall 14 that is arranged around the periphery of the first through hole H1 and connected to the edge of the base plate 10 near the first through hole H1. The light board 11, the diffusion plate 12, and the optical film 13 are located on a side of the hole wall 14 facing away from the first through hole H1.

The hole wall 14 is provided to not only position the light board 11, the diffusion plate 12, and the optical film 13, bust also prevent light emitted by the light source from leaking into the first through hole H1.

In specific implementations, the sizes of the first sub-hole H11 and the second sub-hole H12 can be set according to the size of the camera 17. For example, a gap can be reserved between the hole wall 14 and the camera 17 on one side to facilitate assembly. This reserved gap may, for example, be greater than or equal to 0.1 mm, and less than or equal to 0.4 mm.

Exemplarily, in a direction parallel to the base plate 10, the thickness of the hole wall 14 may be greater than or equal to 0.5 mm and less than or equal to 1.2 mm to facilitate processing and molding.

Exemplarily, as shown in FIG. 1, the hole wall 14 is integrally formed with the base plate 10, thereby reducing the difficulty of assembly.

In some embodiments, as shown in FIG. 1, the backlight module MD further includes a first light-shielding tape 15 adhered to a side of the hole wall 14 facing away from the base plate 10. The orthographic projection of the first light-shielding tape 15 on the base plate 10 falls within the orthographic projection of the hole wall 14 on the base plate 10, and the first light-shielding tape 15 is a closed structure surrounding the first through hole H1.

Since the first light-shielding tape 15 is provided on the surface of the hole wall 14 on the side facing away from the base plate 10, light emitted by the light source can be prevented from leaking into the first through hole H1.

Exemplarily, the first light-shielding tape 15 may be an opaque tape such as a black foam tape.

In some embodiments, as shown in FIG. 1, the backlight module MD further includes a side plate 16 that is connected to an edge of the base plate 10 facing away from the first through hole H1 and located on the periphery of the light board 11, the diffusion plate 12, and the optical film 13.

As shown in FIG. 1, the side plate 16 and the hole wall 14 are located on the same side of the base plate 10. The side plate 16, the hole wall 14, and the base plate 10 together form an accommodation space, in which the light board 11, the diffusion plate 12, and the optical film 13 are located.

As shown in FIG. 1, the side plate 16, the hole wall 14, and the base plate 10 form an integral structure of the back plate.

In some embodiments, as shown in FIG. 1, the backlight module MD further includes a camera 17, a control board 18 and a fixing structure 19. The camera 17 is embedded in the first through hole H1 from the side of the base plate 10 facing away from the light board 11. The camera 17 includes a light-incident surface S1 and a fixed surface S2 arranged opposite to each other, with the light-incident surface S1 facing away from the base plate 10. The control board 18 is fixedly connected to the fixed surface S2, and includes a device area and a blank area. Components of the control board 18 on a side thereof close to the fixed surface S2 are all located in the device area. A hole area is provided with a second through hole H2 penetrating through the control board 18. The fixing structure 19 is disposed on a side of the base plate 10 close to the control board 18, and is configured to fix the control board 18 and the base plate 10.

In some embodiments, as shown in FIG. 1, the fixing structure 19 includes a first boss 191 configured for adhesive fixation with the blank area. No components are arranged in the blank area.

In specific implementations, a plurality of first bosses 191 spaced apart may be provided on the surface of the base plate 10 close to the control board 18. As shown in FIG. 1, two first bosses 191 are provided on the lower surface of the base plate 10, located on opposite sides of the first through hole H1.

Exemplarily, the surface of the first boss 191 facing away from the base plate 10 may be fixed to the blank area by adhesive means such as double-sided tape. The first boss 191 may be integrally formed with the base plate 10.

In some embodiments, the control board 18 further includes a hole area. As shown in FIG. 1, the hole area includes a second through hole H2 penetrating through the control board 18. The fixing structure 19 includes a protruding first screw hole that is configured for fixing with the second through hole H2 via a screw.

For example, a screw may pass through the second through hole H2 and be screwed into the first screw hole, thereby achieving fixation between the control board 18 and the base plate 10. The first screw hole may, for example, be integrally formed with the base plate 10.

In some embodiments, the control board 18 further includes a hole area. As shown in FIG. 1, the hole area includes a second through hole H2 penetrating through the control board 18. The fixing structure 19 includes a protruding first stud that is configured for fixing with the second through hole H2 via a nut.

For example, the second through hole H2 may be sleeved over the first stud, and a nut may be screwed onto the first stud, thereby achieving fixation between the control board 18 and the base plate 10. The first stud may, for example, be integrally formed with the base plate 10.

Exemplarily, the control board 18 has a rectangular structure provided with 4 second through holes H2. The second through holes H2 are located near four inner corners of the rectangular structure respectively.

In some embodiments, a schematic structural diagram of the upper surface of the light board is shown in FIG. 2. As shown in FIG. 2, the light board 11 includes: a substrate 50; a plurality of light-emitting devices 51 spaced apart, located on a side of the substrate 50 facing away from the base plate 10; and a driving device (not shown in the figure), located on a side of the substrate 50 close to the base plate 10.

Here, the light-emitting devices 51 may, for example, be light-emitting diodes (LEDs), etc. The substrate 50 may, for example, be a sheet used for printed circuit boards. The driving device is connected to the light-emitting devices 51, and is configured to drive the light-emitting devices 51 to emit light.

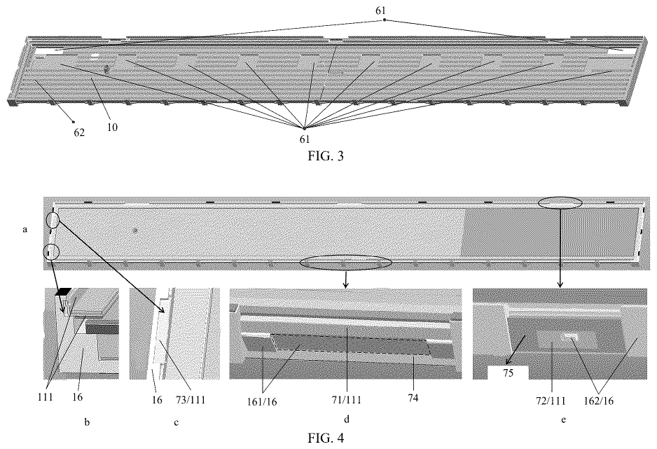

Exemplarily, a schematic structural diagram of a surface of the base plate close to the light board is shown in FIG. 3. As shown in FIG. 3, a first groove 61 is provided on the surface of the base plate 10 close to the light board 11. The first groove 61 partially or completely penetrates the base plate 10, forming an avoidance space for the driving device. An insulating tape is attached to the surface of the first groove 61 close to the driving device.

For example, as shown in FIGS. 3, 10 first grooves 61 partially penetrating the base plate 10 and 2 first grooves 61 completely penetrating the base plate 10 are provided on the surface of the base plate 10 close to the light board 11. The first grooves 61 completely penetrating the base plate 10 are through holes provided in the base plate 10. The depth of the first groove 61 can be set according to the height of the driving device, which is not limited in the present disclosure.

As shown in FIG. 3, an insulating tape is attached to the surface of the first groove 61 close to the driving device, so that short circuits due to contact between the driving device and the base plate 10 can be prevented.

In some embodiments, as shown in FIG. 3, a thermal conductive adhesive 62 for adhering the light board 11 and the base plate 10 is provided on the surface of the base plate 10 close to the light board 11.

Here, the thermal conductive adhesive 62 may, for example, be a double-sided tape with a high thermal conductivity coefficient, thereby timely conducting heat from the light board 11 to the base plate 10, which is beneficial for the performance stability of the light board 11.

Exemplarily, as shown in FIG. 3, the thermal conductive adhesive 62 is provided with an avoidance area at the first groove 61. The thermal conductive adhesive 62 may be attached over the entire surface except for the avoidance area, which can improve the heat dissipation effect of the light board 11. Alternatively, the thermal conductive adhesive 62 may be locally attached to positions corresponding to the light-emitting devices 51 in the light board 11 (as shown in FIG. 3), which can reduce costs while ensuring the heat dissipation effect.

In some embodiments, as shown in FIG. 1, the light board 11 further includes a reflective structure 110 that is disposed on the side of the substrate 50 facing away from the base plate 10 and located around at least one light-emitting device 51. The reflective structure 110 is configured to reflect light incident from the diffusion plate 12 back to the diffusion plate 12. The reflective structure 110 includes at least one of: reflective oil, a reflective sheet, a reflector cup, and a reflective housing.

The reflective structure 110 is provided to improve the utilization rate of light emitted by the light-emitting devices 51. Here, the reflective oil may, for example, be reflective white ink or reflective silver ink coated on the surface of the substrate 50 facing away from the base plate 10. Coating reflective white ink can reduce costs, while coating reflective silver ink can improve reflectivity.

In specific implementations, the reflective structure is avoided at the positions of the light-emitting devices 51 to prevent affecting the emission of light.

In some embodiments, as shown in FIG. 2, the light board 11 includes a plurality of light-emitting devices 51 arranged in a periodic pattern. The light-emitting devices 51 may be arranged at equal intervals, with an arrangement period ranging from 5 mm to 15 mm, for example 9.5 mm.

In FIG. 2, the light board 11 is provided with 120×12 light-emitting devices 51. One light-emitting device 51 is missing at the position of the first through hole H1.

In some embodiments, as shown in FIG. 1, there is a gap between the light board 11 and the diffusion plate 12. The gap is proportional to the arrangement period of the light-emitting devices 51, with a proportionality coefficient greater than or equal to 0.3 and less than or equal to 1.2.

The gap is provided, so that it is beneficial for the light emitted by the plurality of light-emitting devices 51 to mix. In specific implementations, as shown in FIG. 1, the diffusion plate 12 can be placed on a step provided on the side plate 16, thereby ensuring that the gap is fixed.

In the present disclosure, as shown in FIG. 1 and FIG. 4, the backlight module MD may further include a middle frame 111. The middle frame 111 may include a first frame body 71 and a second frame body 72 located on a side of the side plate 16 facing away from the first through hole H1, and may also include a third frame body 73 located on a side of the side plate 16 facing away from the base plate 10. Exemplarily, the material of the middle frame 111 may be polycarbonate or metal. A metal middle frame 111 has higher strength, which is beneficial for reducing the thickness of the middle frame 111, and helps to narrow the bezel and thin the module.

Exemplarily, as shown in FIG. 1, the backlight module MD may further include a foam located on a side of the middle frame 111 facing away from the base plate 10, and a light-shielding tape located on a side of the middle frame 111 close to the base plate 10.

Exemplarily, the metal middle frame 111 may be a sheet metal part made of aluminum alloy or stainless steel, or may be a die-cast part made of aluminum alloy or magnesium alloy.

To improve the structural stability and heat dissipation performance of the backlight module MD, the middle frame 111 is made of stainless steel (e.g., SUS304), and the backplate is a die-cast part made of aluminum alloy.

Exemplarily, at partial positions of the left and right bezels of the backlight module MD, the middle frame 111 is located on a side of the side plate 16 close to the first through hole H1, as shown in FIG. 1 and diagram b of FIG. 4, i.e., the middle frame 111 and the backplate form an inner clamping structure; at partial positions of the left and right bezels of the backlight module MD, the middle frame 111 is folded outward to a side of the side plate 16 facing away from the base plate 10, as shown in diagram c of FIG. 4. The outwardly folded portion of the middle frame 111 (i.e., the third frame body 73) and the side plate 16 may be fixed using double-sided tape.

In diagram c of FIG. 4, two outwardly folded portions of the middle frame 111 (i.e., the third frame body 73) that are spaced apart are provided on the left bezel, and two outwardly folded portions of the middle frame 111 (i.e., the third frame body 73) that are spaced apart are provided on the right bezel.

In some embodiments, as shown in diagram d of FIG. 4, the side plate 16 includes a first side plate 161. The backlight module MD further includes a first frame body 71 located on a side of the first side plate 161 facing away from the first through hole H1. The surface of the first side plate 161 facing away from the first through hole H1 includes a covered area and an exposed area. The covered area is covered by the first frame body 71, and the first frame body 71 is adhesively fixed to the covered area. A second groove 74 is provided in the exposed area, and the groove wall of the second groove 74 includes the surface of the first frame body 71 close to the exposed area.

In specific implementations, a chip-on-film (e.g., a first chip-on-film COF1 or a second chip-on-film COF2) may be provided on a side of the first frame body 71 facing away from the first side plate 161. Accordingly, the second groove 74 is used to avoid the drive chip on the chip-on-film, preventing the drive chip from being squeezed.

Exemplarily, in the normal direction of the first side plate 161, the difference between the groove depth of the second groove 74 (i.e., the depth of the second groove 74 recessed toward the accommodating space) and the thickness of the drive chip may be 0.2 mm to 0.5 mm. The size of the second groove 74 in the direction parallel to the first side plate 161 may be designed according to the size of the drive chip. For example, the difference between the groove length and the length of the drive chip may be 1 mm to 2 mm, and the difference between the groove width and the width of the drive chip may be 1 mm to 2 mm.

In some embodiments, as shown in diagram e of FIG. 4, the side plate 16 includes a second side plate 162. The backlight module MD further includes: a second frame body 72 that is located on a side of the second side plate 162 facing away from the first through hole H1, and snap-fitted to the second side plate 162; and a first rubber pad 75 located on a side of the second frame body 72 facing away from the second side plate 162, and the first rubber pad 75 has a hollowed-out structure at the central area thereof.

Exemplarily, as shown in diagram e of FIG. 4, the first rubber pad 75 may have a frame-like structure. For example, the material of the first rubber pad 75 may be silicone, which is not limited in the present disclosure.

In specific implementations, a chip-on-film (e.g., a first chip-on-film COF1 or a second chip-on-film COF2) may be provided on a side of the first rubber pad 75 facing away from the second side plate 162. Accordingly, the hollowed-out structure is used to avoid the drive chip on the chip-on-film, preventing the drive chip from being squeezed. Since the first rubber pad 75 is easy to replace, it can be compatible with chip-on-films of different structures.

Exemplarily, in the normal direction of the second side plate 162, the difference between the thickness of the first rubber pad 75 and the thickness of the drive chip may be 0.2 mm to 0.5 mm. In the plane of the second side plate 162, the size of the hollowed-out structure may be designed according to the size of the drive chip. For example, the difference between the size of the hollowed-out structure and the size of the drive chip may be 1 mm to 2 mm.

Exemplarily, as shown in FIG. 4, the first side plate 161 and the first frame body 71 may be located at the lower bezel of the backlight module MD, and the second side plate 162 and the second frame body 72 may be located at the upper bezel of the backlight module MD.

Since both the first frame body 71 and the second frame body 72 are located on a side of the side plate 16 facing away from the first through hole H1, the first frame body 71 and the side plate 16, or the second frame body 72 and the side plate 16, form an outer clamping structure.

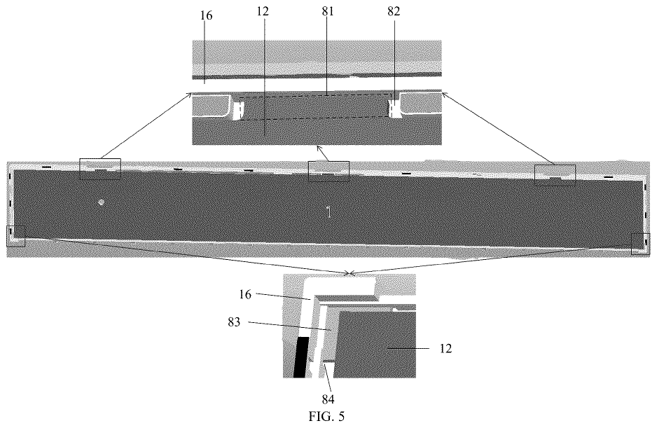

In some embodiments, as shown in FIG. 5, the edge of the diffusion plate 12 is provided with a first lug 81, and the surface of the side plate 16 close to the first through hole H1 (i.e., the inner surface of the side plate 16) is provided a third groove 82. The third groove 82 is configured to position the first lug 81. The backlight module MD further includes: at least one second rubber pad 83 that is disposed between the side plate 16 and the diffusion plate 12, and located on at least three sides of the diffusion plate 12, the second rubber pad 83 and the diffusion plate 12 being in an interference fit; and a first adhesive layer (not shown in the figure) adhered between the diffusion plate 12 and the side plate 16.

The first lugs 81 match with the third grooves 82 in terms of positions and quantities. Exemplarily, as shown in FIGS. 5, 3 third grooves 82 are located at the upper side of the side plate 16, and accordingly, the upper edge of the diffusion plate 12 has 3 first lugs 81.

The second rubber pad 83 and the first lugs 81 may be located on different sides of the diffusion plate 12. Exemplarily, as shown in FIG. 5, the first lugs 81 are located on the upper side of the diffusion plate 12, and the second rubber pad 83 is located on the left, right, and lower sides of the diffusion plate 12.

Exemplarily, as shown in FIG. 5, the orthographic projection of the diffusion plate 12 on the base plate 10 is in the shape of a rectangle. The second rubber pad 83 is an L-shaped rubber pad disposed close to two inner corners of the diffusion plate 12. In FIG. 5, two L-shaped second rubber pads 83 are close to the lower-left inner corner and the lower-right inner corner of the diffusion plate 12 respectively.

The material of the second rubber pad 83 may, for example, be silicone. The interference between the second rubber pad 83 and the diffusion plate 12 may, for example, be 0.1 mm to 0.5 mm, so that the position of the diffusion plate 12 is limited.

The first adhesive layer may, for example, be double-sided tape. The first adhesive layer is adhered between the lower surface of the diffusion plate 12 and the upper surface of the side plate 16, providing partial fixation for the diffusion plate 12 and the side plate 16.

In some embodiments, as shown in FIG. 5, a sixth groove 84 may also be provided on the surface of the side plate 16 close to the first through hole H1. This sixth groove 84 is configured to accommodate the second rubber pad 83 and fix the second rubber pad 83 in the normal direction of the base plate 10, preventing the second rubber pad 83 from floating upward.

In some embodiments, as shown in FIG. 1, in the normal direction of the base plate 10, the surface of the second rubber pad 83 facing away from the base plate 10 is lower than the surface of the diffusion plate 12 facing away from the base plate 10. This prevents the second rubber pad 83 from squeezing the optical film 13 and causing wrinkles in the film.

The height difference between the surface of the second rubber pad 83 facing away from the base plate 10 and the surface of the diffusion plate 12 facing away from the base plate 10 may, for example, be 0.2 mm.

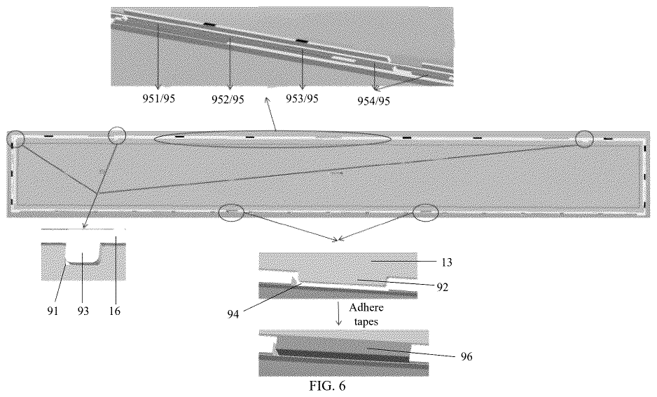

In some embodiments, as shown in FIG. 6, the edge of the optical film 13 is provided with a first notch 91 and a second lug 92. The first notch 91 and the second lug 92 are located on opposite edges of the optical film 13, respectively. The surface of the side plate 16 close to the first through hole H1 (i.e., the inner surface of the side plate 16) is provided with a second boss 93 and a fourth groove 94. The second boss 93 is configured to position the first notch 91, and the fourth groove 94 is configured to position the second lug 92. The backlight module MD further includes a second adhesive layer 95. The second adhesive layer 95 includes a plurality of adhesive portions adhered between different optical films 13 and the side plate 16.

The second boss 93 matches with the first notch 91 in terms of positions and quantities, and the fourth groove 94 matches with the second lug 92 in terms of positions and quantities. Exemplarily, as shown in FIGS. 6, 3 second bosses 93 are located at the upper side of the side plate 16, and accordingly, the upper edge of the optical film 13 is provided with 3 first notches 91. Two fourth grooves 94 are located at the lower side of the side plate 16, and accordingly, the lower edge of the optical film 13 is provided with 2 second lugs 92.

Exemplarily, as shown in FIG. 6, single-sided tape 96 may also be adhered on the side of the second lug 92 and the fourth groove 94 facing away from the base plate 10 to fix the optical film 13 to the side plate 16.

The second adhesive layer 95 may, for example, be a double-sided tape, adhered between the lower surface of the optical film 13 and the upper surface of the side plate 16. In FIG. 6, the second adhesive layer 95 includes the following adhesive portions arranged in sequence from left to right: an adhesive portion 951 for fixing the diffusion sheet, an adhesive portion 952 for fixing the lower prism sheet, an adhesive portion 953 for fixing the upper prism sheet, and an adhesive portion 954 for fixing the brightness enhancement film.

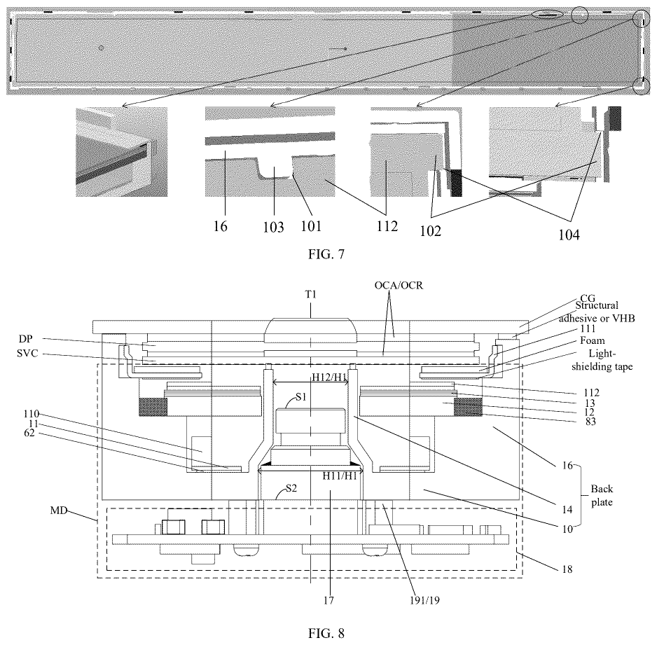

In some embodiments, as shown in FIG. 1 and FIG. 7, the backlight module MD further includes a privacy screen protector 112 located on the side of the optical film 13 facing away from the diffusion plate 12. The orthographic projection of the privacy screen protector 112 on the diffusion plate 12 partially covers the diffusion plate 12, and the orthographic projection of the privacy screen protector 112 on the base plate 10 does not overlap with the orthographic projection of the first through hole H1 on the base plate 10. The privacy screen protector 112 is configured to reduce the divergence angle of the incident light, thereby achieving light collection and privacy protection.

In specific implementations, the privacy screen protector 112 may be applied across the entire surface or on a local area. Exemplarily, as shown in FIG. 1 and FIG. 7, the privacy screen protector 112 is only provided in the right one-third area of the backlight module MD. The area where the privacy screen protector 112 is provided can be adjusted according to the size of the privacy protection area desired by the customer (full-screen privacy protection or partial privacy protection).

Brightness loss will occur due to the privacy screen protector 112. Assuming the loss value is “a”, when the driving current of the backlight is the same, the brightness of the privacy area and the non-privacy area will be different. Therefore, local dimming can be performed on the backlight module MD, i.e., by setting different driving currents for different areas, the loss value “a” is compensated, making the brightness of the privacy area and the non-privacy area consistent.

In some embodiments, as shown in FIG. 7, the edge of the privacy screen protector 112 is provided with a second notch 101 and a third lug 102. The second notch 101 and the third lug 102 are located on two adjacent edges of the optical film 13, respectively. The surface of the side plate 16 close to the first through hole H1 (i.e., the inner surface of the side plate 16) is provided with a third boss 103 and a fifth groove 104. The third boss 103 is configured to position the second notch 101, and the fifth groove 104 is configured to position the third lug 102.

The third boss 103 matches with the second notch 101 in terms of positions and quantities, and the fifth groove 104 matches with the third lug 102 in terms of positions and quantities. Exemplarily, as shown in FIGS. 7, 1 third boss 103 is located at the upper side of the side plate 16, and accordingly, the upper edge of the privacy screen protector 112 is provided with 1 second notch 101. Two fifth grooves 104 are located at the right side of the side plate 16, and accordingly, the right edge of the privacy screen protector 112 is provided with 2 third lugs 102.

In some embodiments, as shown in FIG. 1, the backlight module MD further includes a third frame body 73, a third adhesive layer 113 and a second light-shielding tape 114. The third frame body 73 is located on the side of the side plate 16 and the privacy screen protector 112 facing away from the base plate 10. The third frame body 73 includes a privacy frame body 731 and a non-privacy frame body 732, and the privacy frame body 731 is adjacent to the privacy screen protector 112. The third adhesive layer 113 is adhered between the privacy screen protector 112 and the privacy frame body 731. The second light-shielding tape 114 is adhered on the surface of the non-privacy frame body 732 close to the optical film 13.

The third adhesive layer 113 may, for example, be a double-sided tape, adhered between the lower surface of the privacy frame body 731 and the upper surface of the privacy screen protector 112.

As shown in FIG. 1, the gap between the privacy frame body 731 and the privacy screen protector 112 is “b”. Considering the thickness of the privacy screen protector 112 is “c”, the privacy screen protector 112 is provided so that the gap between the non-privacy frame body 732 and the optical film 13 “b”+“c”. Thus, due to the different gaps in the area with the privacy screen protector 112 and the area without the privacy screen protector 112, the edge of the film may be seen at large viewing angles, i.e., a bright edge issue of the film. By adhering the second light-shielding tape 114 on the surface of the non-privacy frame body 732 close to the optical film 13, the gap difference between the area with the privacy screen protector 112 and the area without the privacy screen protector 112 can be reduced, thereby solving the bright edge issue of the film.

Exemplarily, the second light-shielding tape 114 may be an opaque tape such as a black foam tape. The thickness of the second light-shielding tape 114 may, for example, be the thickness of the privacy screen protector 112.

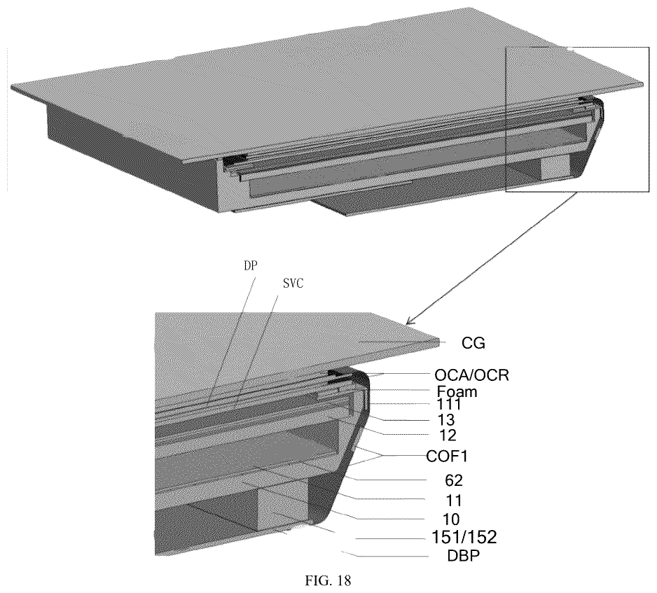

The present disclosure also provides a display device. As shown in FIG. 8 or FIG. 18, the display device includes: a display panel DP with an active display area; and the backlight module MD according to any of the embodiments, which is located on a side of the display panel DP facing away from the display surface, and configured to provide a backlight source for the display panel DP.

Those skilled in the art can understand that the display device provided by the present disclosure has the advantages of the above-described backlight module MD. The display device provided by the present disclosure can be integrated into products such as notebooks, monitors,, and can serve as a display in many fields such as in-vehicle displays and consumer electronics.

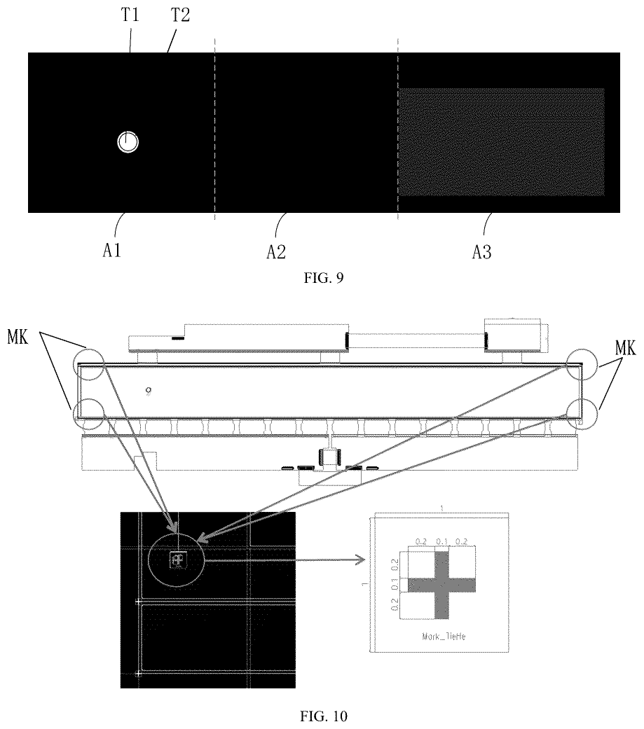

In some embodiments, as shown in FIG. 9, the active display area includes a plurality of sub-display areas. For example, the active display area includes three sub-display areas arranged along a long side direction, namely a first sub-display area A1, a second sub-display area A2, and a third sub-display area A3. The first sub-display area A1 is configured to implement instrument display functions, the second sub-display area A2 is configured to implement central control display functions, and the third sub-display area A3 is configured to implement audio-visual display functions. In this example, the display panel DP is integrated with functions such as instrument display, central control display, and co-driver audio-visual display.

Exemplarily, an aspect ratio of the display panel DP may be 10:1.

In some embodiments, the display panel DP is integrated with a touch circuit, which can replace the structure of the display panel DP plus an external touch screen. This can reduce the thickness of the display module, lower assembly complexity and control module complexity, and reduce costs. The touch circuit is configured to implement touch functionality.

In some embodiments, as shown in FIG. 8, the display device further includes a privacy panel SVC located between the display panel DP and the backlight module MD. The privacy panel SVC includes a privacy area including a driving structure and functional particles. The driving structure is configured to establish an electric field, which drives the functional particles to move, thereby enabling a target sub-display area to be in a privacy state or a sharing state. The target sub-display area includes one or more sub-display areas.

The privacy panel SVC is provided, and a driving signal is supplied to the driving structure in the privacy panel SVC via a driving component. The driving structure establishes an electric field in response to the driving signal, and the functional particles move under the influence of the electric field. Therefore, one or more sub-display areas (i.e., the target sub-display area) in the display panel DP is in a privacy state or a sharing state. A switching between the privacy state and the sharing state can be achieved by providing different driving signals. The target sub-display area can be part or all of the sub-display areas in the display panel DP, meaning the privacy panel SVC can locally adjust the privacy/sharing state of the display panel DP.

Thus, the display area displaying an audio-visual screen can be switched to the privacy state during driving, so as to prevent the audio-visual screen from distracting the driver, thereby improving driving safety. In a safe environment, such as when the vehicle is parked, the display area displaying an audio-visual screen can be switched to the sharing state, allowing the driver and the passenger to share audio-visual entertainment, enhancing the user experience.

The display panel DP is used for displaying images, and the privacy panel SVC can be used for pixel-level adjustment between the sharing state and the privacy state. By placing the privacy panel SVC on the side of the display panel DP facing away from the light-emitting surface, the privacy panel SVC can be prevented from shielding the touch functionality of the display panel DP.

In some embodiments, as shown in FIG. 1, the orthographic projections of the privacy panel SVC and the privacy screen protector 112 on the display panel DP overlap with each other, and the privacy panel SVC and the privacy screen protector 112 cooperate to achieve various privacy effects.

In some embodiments, as shown in FIG. 10, the display device further includes a plurality of alignment mark groups MK spaced apart, so as to achieve precise alignment between the display panel DP and the privacy panel SVC. Each alignment mark group MK includes: a first alignment mark located in a border area on the display panel DP, the border area being located on at least one side of the active display area; and a second alignment mark located on the privacy panel SVC. The orthographic projection of the second alignment mark on the display panel DP at least partially overlaps with the first alignment mark.

Exemplarily, both the display panel DP and the privacy panel SVC are in a shape of rectangle, and the alignment mark groups MK are located near the inner corners of the rectangle.

In FIG. 10, the first alignment mark and the second alignment mark in the same alignment mark group MK coincide. Exemplarily, the orthographic projections of the first alignment mark and the second alignment mark on the display panel DP are both cross-shaped.

FIG. 10 exemplarily shows a dimension of the first alignment mark or the second alignment mark. This dimension can be designed according to the dimensions and requirements of the display panel DP and the privacy panel SVC. Since the first alignment marks and the second alignment marks are used for achieving alignment, they cannot be covered by polarizers, protective adhesives, etc.

In some embodiments, as shown in FIG. 8, the display device further includes a cover plate CG disposed close to the light-emitting surface of the display panel DP.

To achieve a precise alignment between the display panel DP and the privacy panel SVC, in one example, during the alignment and lamination process, the display panel DP and the privacy panel SVC are aligned and laminated together based on the first and second alignment marks first, and then aligned and laminated with the cover plate CG.

In another example, during the alignment and lamination process, the display panel DP and the privacy panel SVC are first aligned and laminated together based on center point alignment, and then aligned and laminated with the cover plate CG.

In yet another example, during the alignment and lamination process, a fixture can be used for edge-to-edge alignment and lamination. In this case, the tolerance for the aligned edges is well controlled, while the opposite edges may have larger tolerances due to accumulated tolerances.

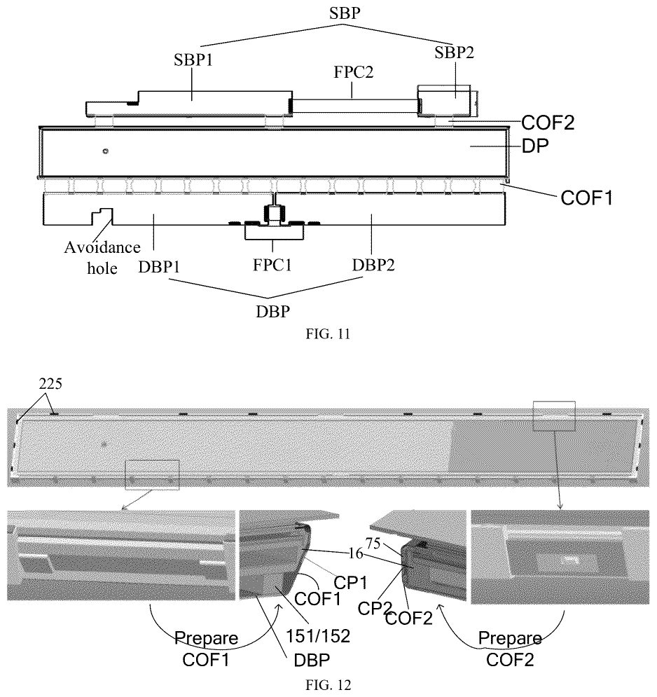

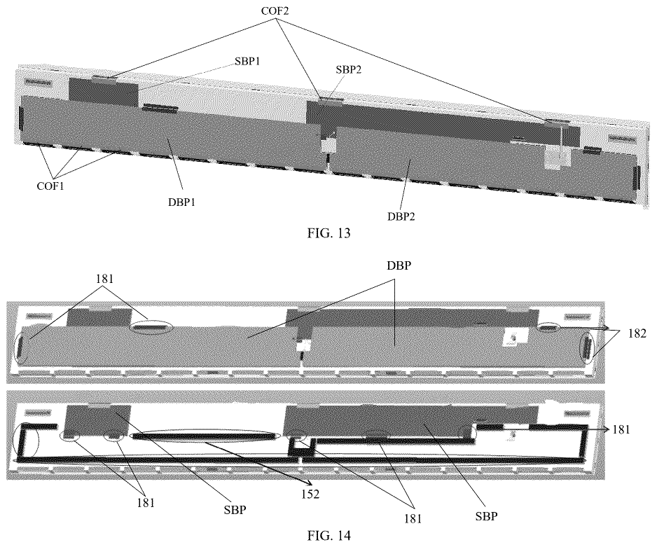

In some embodiments, as shown in FIGS. 11 to 13, the display device further includes: a first chip-on-film COF1, with a first end bonded to the display panel DP and a second end bent to the side of the backlight module MD facing away from the display panel DP (not bent in FIG. 11, the bent state is shown in FIG. 12); and a second chip-on-film COF2, with a first end bonded to the privacy panel SVC and a second end bent to the side of the backlight module MD facing away from the display panel DP (not bent in FIG. 11, the bent state is shown in FIG. 12). The first chip-on-film COF1 and the second chip-on-film COF2 are disposed near opposite edges of the display device, respectively.

Exemplarily, as shown in FIGS. 11 to 13, the first chip-on-film COF1 has 16 lines exiting from the lower side of the display module, and the second chip-on-film COF2 has 3 lines exiting from the upper side of the display module.

To ensure signal stability, in some embodiments, as shown in FIG. 12, the display device further includes: a first drive chip CP1, connected to the first chip-on-film COF1 and located on the side of the first chip-on-film COF1 close to the backlight module MD; and a second drive chip CP2, connected to the second chip-on-film COF2 and located on the side of the second chip-on-film COF2 close to the backlight module MD. An electromagnetic shielding tape is attached to the side of the first chip-on-film COF1 facing away from the first drive chip CP1 and the side of the second chip-on-film COF2 facing away from the second drive chip CP2.

Here, the electromagnetic shielding tape, such as EMI Tape, is a tape with electromagnetic shielding functionality.

Furthermore, the electromagnetic shielding tape can also have thermal conductivity. The electromagnetic shielding tape covering the first chip-on-film COF1 or the second chip-on-film COF2 also overlaps with the surface of the backplate facing away from the display panel DP, thereby conducting heat from the drive chips to the backplate. This prevents the drive chips from overheating and causing defects, which is beneficial for achieving a display module with higher resolution.

In some embodiments, as shown in FIGS. 11 to 13, the display device further includes: a display circuit board DBP, connected to the second end of the first chip-on-film COF1 and located on the side of the backlight module MD facing away from the display panel DP. The display circuit board DBP includes a first display circuit board DBP1, a second display circuit board DBP2, and a first flexible circuit board FPC1 connecting the first display circuit board DBP1 and the second display circuit board DBP2. For example, both ends of the first flexible circuit board FPC1 can be connected to connectors on the first display circuit board DBP1 and the second display circuit board DBP2, respectively.

In some embodiments, as shown in FIGS. 11 to 13, the display device further includes: a privacy circuit board SBP, connected to the second end of the second chip-on-film COF2 and located on the side of the backlight module MD facing away from the display panel DP. The privacy circuit board SBP includes a first privacy circuit board SBP1, a second privacy circuit board SBP2, and a second flexible circuit board FPC2 connecting the first privacy circuit board SBP1 and the second privacy circuit board SBP2. For example, both ends of the second flexible circuit board FPC2 can be connected to connectors on the first privacy circuit board SBP1 and the second privacy circuit board SBP2, respectively.

To ensure signal quality, in some embodiments, an electromagnetic shielding tape is attached to the side of the first flexible circuit board FPC1 facing away from the backlight module MD and the side of the second flexible circuit board FPC2 facing away from the backlight module MD.

Exemplarily, an avoidance hole for the camera 17 can also be provided on the display circuit board DBP (as shown in FIG. 11) or the privacy circuit board SBP.

To prevent metal foreign objects from falling onto electronic components and causing short circuits, in some embodiments, an insulating tape is attached to the surface of the display circuit board DBP and the privacy circuit board SBP facing away from the display panel DP.

In some embodiments, the display device further includes: the display circuit board DBP disposed close to the first chip-on-film COF1, and the privacy circuit board SBP disposed close to the second chip-on-film COF2. In the normal direction of the display panel DP, the display circuit board DBP and the privacy circuit board SBP partially overlap, and there is a gap between the display circuit board DBP and the privacy circuit board SBP.

Since the sum of the widths of the display circuit board DBP and the privacy circuit board SBP is greater than the width of the display module (i.e., the length of the short side), to prevent interference between the display circuit board DBP and the privacy circuit board SBP, the display circuit board DBP (as shown in FIG. 12) or the privacy circuit board SBP can be raised in the normal direction of the display panel DP, ensuring a gap between the display circuit board DBP and the privacy circuit board SBP, thereby separating them.

It should be noted that, instead of raising the display circuit board DBP or the privacy circuit board SBP, both the display circuit board DBP and the privacy circuit board SBP can be attached to the lower surface of the backplate if the space within the display module is sufficient.

The following description uses raising the display circuit board DBP (as shown in FIG. 12) as an example for illustration.

For example, to raise the display circuit board DBP, the display device further includes a raising structure 151. The raising structure 151 is disposed on the side of the backlight module MD close to the display circuit board DBP, and configured to raise the display circuit board DBP in the normal direction of the display panel DP.

In some examples, the raising structure 151 includes a third rubber pad 152 that is adhesively fixed to both the backlight module MD and the display circuit board DBP. In this example, the third rubber pad 152 can be adhesively fixed to the backplate and a component-free area on the display circuit board DBP using a double-sided tape, and no holes need to be drilled in the display circuit board DBP in this example.

In some other examples, the raising structure 151 includes a protruding second screw hole (not shown in the figure) for fixing the display circuit board DBP with a screw. In this example, holes can be drilled in a component-free area on the display circuit board DBP, with the hole positions corresponding to the positions of the second screw holes. The second screw hole and the backplate can be an integrated structure. Exemplarily, the protruding second screw hole can be formed directly by stamping a convex bulge and tapping it.

In yet other examples, the raising structure 151 includes a protruding second stud (not shown in the figure) for fixing the display circuit board DBP with a nut. In this example, holes can be drilled in a component-free area on the display circuit board DBP, with the hole positions corresponding to the positions of the second studs. The second stud and the backplate can be an integrated structure.

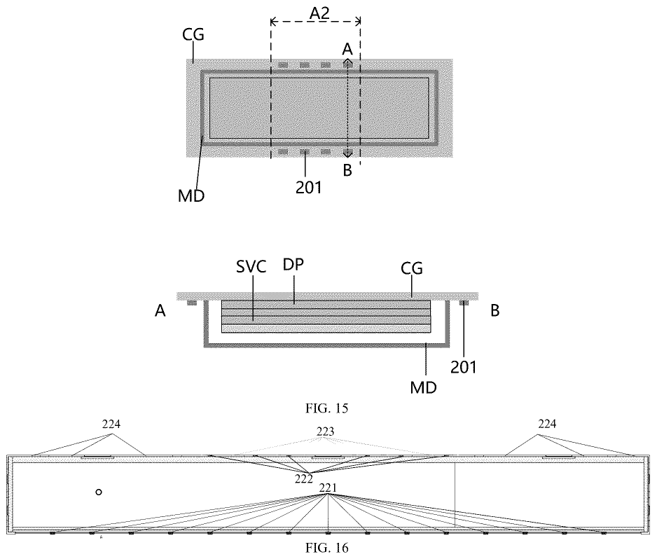

To achieve grounding protection, in some embodiments, as shown in FIG. 14, the privacy circuit board SBP includes: a first exposed metal area (not shown in the figure) close to the backlight module MD, and a second exposed metal area facing away from the backlight module MD. The first exposed metal area is connected to the backlight module MD via a conductive double-sided tape. The second exposed metal area is disposed near the edge of the privacy circuit board SBP and is connected to the backlight module MD via a single-sided conductive tape 181, i.e., the second exposed metal area and the backplate are bridged by the single-sided conductive tape 181.

To achieve grounding protection, in some embodiments, as shown in FIG. 14, the display circuit board DBP includes: a third through hole (not shown in the figure) for screws or studs to pass through, where the hole wall 14 of the third through hole includes a third exposed metal area; and a fourth exposed metal area facing away from the backlight module MD, disposed near the edge of the display circuit board DBP. The fourth exposed metal area is connected to the backlight module MD via a single-sided conductive tape 182.

In this embodiment, when the display circuit board DBP is raised, the single-sided conductive tape 182 bridging the fourth exposed metal area and the backplate is Z-shaped.

For example, an exposed copper layer can be provided at the third through hole, and the fixing screw or nut can conductively connect the display circuit board DBP and the backplate.

In some embodiments, the active display area includes a first display partition and a second display partition. The first display circuit board DBP1 is configured to drive the first display partition, and the second display circuit board DBP2 is configured to drive the second display partition. As shown in FIG. 2, the light board 11 includes a first light board 52 and a second light board 53 spliced together. The first light board 52 is configured to provide a light source for the first display partition, and the second light board 53 is configured to provide a light source for the second display partition. The first light board 52 is connected to the first display circuit board DBP1, and the second light board 53 is connected to the second display circuit board DBP2.

Exemplarily, the light board 11 can be provided with a connector connected to one end of a flexible circuit board. The other end of the flexible circuit board is connected to a circuit board.

Exemplarily, the splicing gap between the first light board 52 and the second light board 53 can be 0.5 mm to 2 mm.

In some embodiments, as shown in FIG. 9, the active display area includes the first sub-display area A1. The display panel DP further includes: a first light-transmitting area T1, and a first light-shielding area T2 located on at least one side of the first light-transmitting area T1. The first sub-display area A1 is located on at least one side of the first light-shielding area T2. The orthographic projection of the first through hole H1 on the display panel DP at least partially overlaps with the first light-transmitting area T1.

Exemplarily, as shown in FIG. 9, the first light-shielding area T2 is arranged surrounding the first light-transmitting area T1, and the first sub-display area A1 is arranged surrounding the first light-shielding area T2.

It should be noted that the polarizer of the display panel DP can be avoided in the first light-transmitting area T1 to prevent from affecting the transmittance of the first light-transmitting area T1.

The first sub-display area A1 can be used for display instruments. Since instruments are generally displayed directly to the driver, the first light-transmitting area T1 can be provided in the first sub-display area A1, such as the left one-third area of the display module, to facilitate capturing the driver's driving state.

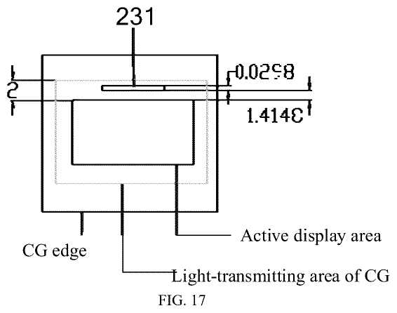

In some embodiments, as shown in FIG. 15, the active display area includes a second sub-display area A2. The display device further includes vibration exciters 201 located on the side of the cover plate CG close to the display panel DP. The vibration exciters 201 are symmetrically disposed on opposite sides of the second sub-display area A2 and near the edge of the cover plate CG. In FIG. 15, the top diagram is a schematic plan view of the display device, and the bottom diagram is a schematic cross-sectional view of the display device along line AB.

Different tactile feedback for physical keys can be achieved in the second sub-display area A2 by providing vibration exciters 201, thereby improving the interactivity. Additionally, vibration uniformity in the second sub-display area A2 can be improved by symmetrically arranging the vibration exciters 201.

The second sub-display area A2 can be used for central control display, such as the middle one-third area of the display module. Accordingly, the vibration exciters 201 are attached along the two long sides of the cover plate CG and located in the edge areas on both sides of the second sub-display area A2.

Exemplarily, as shown in FIG. 15, the dimensions of a single vibration exciter 201 are 5.0 mm*10.0 mm*0.5 mm.

Exemplarily, as shown in FIG. 15, the orthographic projection of the vibration exciter 201 on the cover plate CG is outside the orthographic projection of the backlight module MD on the cover plate CG. The distance between the vibration exciter 201 and the edge of the cover plate CG, as well as the distance between the vibration exciter 201 and the edge of the backlight module MD, are both greater than 0.5 mm. The distance between the edge of the cover plate CG and the edge of the backlight module MD is 8 mm to 15 mm.

Exemplarily, the vibration exciter 201 and the cover plate CG can be adhered using a double-sided tape.

Exemplarily, the distance between vibration exciters 201 is an integer multiple of the wavelength node, which can generate a textured haptic feedback. The distance between the vibration exciters 201 can be, for example, greater than or equal to 1 mm and less than or equal to 10 mm, which can be specifically determined based on the required vibration mode, etc.

In specific implementations, each vibration exciter 201 has a positive control wire and a negative control wire, which are bundled and fixed on the lower surface of the cover plate CG, uniformly connected to a control circuit board.

To drive the vibration of the display panel DP, an optical adhesive with a low elastic modulus can be used to adhere the cover plate CG and the display panel DP.

Additionally, a structural adhesive 224 with a low elastic modulus and double-sided tape (such as 3M 59 series VHB tape) can be used to adhere the side plate 16 and the cover plate CG. The inventors found that if only VHB tape or foam tape is used to adhere the side plate 16 and the cover plate CG, due to the lower strength of VHB tape or foam tape compared to structural adhesive 224 or hot melt adhesive, the adhesion width generally needs to be 3~5 mm or more, requiring more space and affecting the bezel. If only hot melt adhesive/silicone rubber/structural adhesive 224 is used, due to the large number of first chip-on-films COF1 on the lower bezel with gaps not exceeding 10 mm, the dispensing process is somewhat affected.

In some embodiments, as shown in FIG. 16, the display device further includes an adhesive structure disposed between the side plate 16 and the cover plate CG. The adhesive structure can include: a first double-sided tape 221 located between adjacent first chip-on-films COF1.

In this embodiment, as shown in FIG. 16, the adhesive structure may further include a second double-sided tape 222 located between adjacent second chips-on-film COF2. The second double-sided tape 222 is disposed on a side of the second sub-display area A2 facing away from the first double-sided tape 221. The second double-sided tape 222 and the first double-sided tape 221 are symmetrically arranged on opposite sides of the second sub-display area A2.

In this embodiment, as shown in FIG. 16, the adhesive structure may further include: a single-sided foam tape 223, with the adhesive side facing the side plate 16, located between two adjacent second double-sided tapes 222.

In this embodiment, as shown in FIG. 16, the adhesive structure may further include: a structural adhesive 224 located among the first double-sided tape 221, the second double-sided tape 222, and the single-sided foam tape 223, with the same thickness as the first double-sided tape 221 and the second double-sided tape 222. That is, the structural adhesive 224 is applied in areas other than those occupied by the first double-sided tape 221, the second double-sided tape 222, and the single-sided foam tape 223.

This embodiment uses a combination of multiple adhesives to bond the side plate 16 and the cover plate CG, which can improve bonding strength, facilitate a narrow bezel, and enhance vibration transmission effectiveness.

Exemplarily, as shown in FIG. 16, the first double-sided tape 221 is placed between the first chips-on-film COF1 on the lower side. On the upper side of the second sub-display area A2, the second double-sided tape 222 is symmetrically arranged relative to the first double-sided tape 221, the second double-sided tape 222 needs to avoid the second chips-on-film COF2. The single-sided foam tape 223 is placed between the second double-sided tapes 222 on the upper side of the second sub-display area A2 to reduce the elastic modulus in that area and improve vibration effects.

The first double-sided tape 221 and the second double-sided tape 222 may, for example, be VHB tape.

To ensure the structural strength of the display module fixation, the width of the structural adhesive 224 in the direction parallel to the base plate 10 may, for example, be between 1.5 mm and 3 mm.

In this embodiment, as shown in FIG. 12, the adhesive structure may further include: a plurality of separated fourth bosses 225, located on the surface of the side plate 16 close to the cover plate CG. The fourth bosses 225 are configured to limit the height between the cover plate CG and the side plate 16. A single-sided tape 96 is attached to the surface of the fourth bosses 225 close to the cover plate CG to prevent the backplate from scratching the cover plate CG.

Exemplarily, the height of the fourth bosses 225 may be 0.6 mm, with a spacing of 30 mm to 100 mm.

In some embodiments, as shown in FIG. 1, the display device further includes: a light-transmitting ink (not shown in the figure), located between the cover plate CG and the display panel DP. The orthographic projection of the light-transmitting ink on the backlight module MD at least partially overlaps with the first through hole H1, and it is used to transmit light of a preset wavelength band, which does not overlap or partially overlaps with the visible light spectrum. The preset wavelength band may, for example, be a non-visible light band, and the light-transmitting ink is used for the camera 17 to capture information.

In some embodiments, as shown in FIG. 17, the display panel DP further includes: a border area, located on at least one side of the active display area; and an ambient light sensor 231, located in the border area and configured to sense the intensity of ambient light.

By integrating the ambient light sensor 231 into the display panel DP, the interior space can be saved. The screen brightness can be automatically adjusted based on the sensed ambient light intensity, enhancing driving safety.

Exemplarily, the ambient light sensor 231 can be centrally located in one border area (such as the upper border area shown in FIG. 17). As shown in FIG. 17, the dimensions of the ambient light sensor 231 are 15 mm*30 μm, the distance to the active display area is 1.4 mm, it is located in the light-transmitting area of the cover plate CG, and does not overlap with the light-shielding area (ink shading) of the cover plate CG, to allow ambient light reception. For example, the distance between the inner edge of the light-shielding area of the cover plate CG and the ambient light sensor 231 can be greater than or equal to 0.5 mm.

Considering lamination and manufacturing tolerances, the light-transmitting area of the cover plate CG can cover the active display area, and the distance between the boundary of the light-transmitting area of the cover plate CG and the boundary of the active display area should be greater than or equal to 1 mm (e.g., 1 mm on the left and right sides, 2 mm on the top and bottom sides). This facilitates the lamination production of large-sized display modules and prevents the light-shielding area of the cover plate CG from covering the active display area due to lamination deviations, which would cause display image loss.

Exemplarily, the ambient light sensor 231 can be connected to a printed circuit board via a chip-on-film (e.g., the first chip-on-film COF1 on the left end). During implementation, the ambient light sensing function can be combined with the local dimming function of the backlight module MD to automatically adjust the brightness of the backlight module MD based on the sensed ambient light intensity.

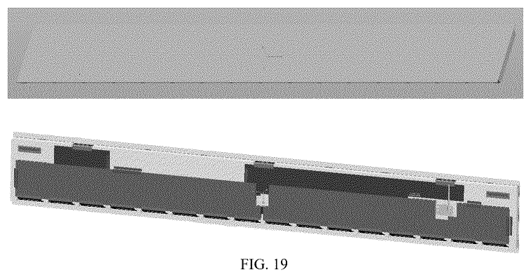

Referring to FIG. 19, a top surface diagram and a bottom surface diagram of the display module are exemplarily shown from top to bottom.

In this disclosure, “a plurality of” means two or more, and “at least one” means one or more, unless explicitly specified otherwise.

In this disclosure, terms such as “upper”, “lower”, etc., indicating orientation or positional relationships are based on the orientations or positional relationships shown in the drawings, and are only for the convenience of describing the disclosure and simplifying the description, rather than indicating or implying that the referred apparatus or elements must have a specific orientation, be constructed, or operate in a specific orientation. Therefore, they should not be construed as limiting the disclosure.

As used herein, the terms “comprise”, “include”, or any other variation thereof are intended to cover a non-exclusive inclusion, such that a process, method, article, or device that includes a list of elements includes not only those elements but may also include other elements not expressly listed or inherent to such process, method, article, or device. Without further limitation, an element defined by the phrase “comprising a . . . ” does not exclude the presence of additional identical elements in the process, method, article, or device that includes the said element.

Terms such as “one embodiment”, “some embodiments”, “exemplary embodiment”, “one or more embodiments”, “example”, “one example”, “some examples”, etc., used herein are intended to indicate that specific features, structures, materials, or characteristics related to the embodiment or example are included in at least one embodiment or example of this disclosure. The illustrative references to the above terms do not necessarily refer to the same embodiment or example. Furthermore, the described specific features, structures, materials, or characteristics may be combined in any suitable manner in any one or more embodiments or examples.

In this document, relational terms such as first and second are used merely to distinguish one entity or operation from another, without necessarily requiring or implying any actual such relationship or order between them.

When describing some embodiments, the terms “coupled” and “connected” may be used. For example, the term “connected” may be used in describing some embodiments to indicate that two or more components are in direct physical or electrical contact with each other. Similarly, the term “coupled” may be used in describing some embodiments to indicate that two or more components are in direct physical or electrical contact. However, the term “coupled” or “communicatively coupled” may also mean that two or more components are not in direct contact with each other but still cooperate or interact. The embodiments disclosed herein are not necessarily limited to the content herein.

“At least one of A, B, and C” has the same meaning as “at least one of A, B, or C”, both including the following combinations of A, B, and C: only A, only B, only C, a combination of A and B, a combination of A and C, a combination of B and C, and a combination of A, B, and C.

“A and/or B” includes the following three combinations: only A, only B, and a combination of A and B.

As used herein, depending on the context, the term “if” may optionally be construed to mean “when”, “upon”, “in response to determining”, or “in response to detecting”. Similarly, depending on the context, the phrase “if it is determined . . . ” or “if [a stated condition or event] is detected” may optionally be construed to mean “upon determining . . . ” , “in response to determining . . . ”, “upon detecting [the stated condition or event]”, or “in response to detecting [the stated condition or event]”.

The use of “for” or “configured to” herein implies open and inclusive language, which does not exclude devices that are suitable or configured to perform additional tasks or steps.

The use of “based on” or “according to” herein implies openness and inclusivity. A process, step, calculation, or other action based on one or more stated conditions or values may, in practice, be based on additional conditions or values beyond those stated. A process, step, calculation, or other action according to one or more stated conditions or values may, in practice, be performed according to other conditions or values beyond those stated.

As used herein, “about”, “approximately”, or “substantially” includes the stated value and the average value within an acceptable deviation range of a specific value, where the acceptable deviation range is determined by a person of ordinary skill in the art, considering the measurement in question and the error associated with the measurement of the specific quantity (i.e., the limitations of the measurement system).

As used herein, “parallel”, “perpendicular”, “equal”, “flush” include the stated situations and situations approximating the stated ones, where the range of approximation is within an acceptable deviation range. The acceptable deviation range is determined by a person of ordinary skill in the art, considering the measurement in question and the error associated with the measurement of the specific quantity (i.e., the limitations of the measurement system). For example, “parallel” includes absolutely parallel and approximately parallel, where the acceptable deviation range for approximately parallel can be, for instance, a deviation within 5°. “Perpendicular” includes absolutely perpendicular and approximately perpendicular, where the acceptable deviation range for approximately perpendicular can also be, for example, a deviation within 5°. “Equal” includes absolutely equal and approximately equal, where the acceptable deviation range for approximately equal can be, for example, a difference between the two equal items less than or equal to 5% of either. “Flush” includes absolutely flush and approximately flush, where the acceptable deviation range for approximately flush can be, for example, a distance between the two flush items less than or equal to 5% of the dimension of either.

It should be understood that when a layer or element is referred to as being “on” another layer or substrate, it can be directly on the other layer or substrate, or there can be an intermediate layer between the layer or element and the other layer or substrate.

Exemplary embodiments are described herein with reference to cross-sectional and/or plan views as idealized exemplary drawings. In the drawings, the thicknesses of layers and regions are exaggerated for clarity. Thus, variations in the shapes of the illustrations due to, for example, manufacturing techniques and/or tolerances, are to be expected. Therefore, the exemplary embodiments should not be construed as limited to the shapes of the regions illustrated herein but are to include deviations in shapes caused by, for example, manufacturing. For example, an etched region illustrated as a rectangle will typically have rounded features. Therefore, the regions illustrated in the figures are schematic in nature, and their shapes are not intended to illustrate the actual shape of a region of a device and are not intended to limit the scope of the exemplary embodiments.

Finally, it should be noted that the above embodiments are only used to illustrate the technical solutions of the present disclosure and not to limit them. Although the present disclosure has been described in detail with reference to the foregoing embodiments, those of ordinary skill in the art should understand that they can still modify the technical solutions described in the foregoing embodiments or make equivalent substitutions for some of the technical features. Such modifications or substitutions do not cause the essence of the corresponding technical solutions to depart from the spirit and scope of the technical solutions of the embodiments of the present disclosure.

1. A backlight module, comprising:
a base plate;
a light board disposed on a side of the base plate, configured to provide a light source;
a diffusion plate stacked on a side of the light board facing away from the base plate;
an optical film stacked on a side of the diffusion plate facing away from the base plate; and
a first through hole penetrating through the base plate, the light board, the diffusion plate, and the optical film along a normal direction of the base plate.

2. The backlight module according to claim 1, wherein the first through hole comprises:
a first sub-hole close to the base plate and a second sub-hole facing away from the base plate, wherein an orthographic projection of the first sub-hole on the base plate is greater than an orthographic projection of the second sub-hole on the base plate in terms of dimensions, and the orthographic projection of the first sub-hole on the base plate covers the orthographic projection of the second sub-hole on the base plate.

3. The backlight module according to claim 1, further comprising:
a hole wall arranged around the first through hole and connected to an edge of the base plate adjacent to the first through hole, wherein the light board, the diffusion plate, and the optical film are located on a side of the hole wall facing away from the first through hole; and
a first light-shielding tape adhered to a side of the hole wall facing away from the base plate, wherein an orthographic projection of the first light-shielding tape on the base plate is within an orthographic projection of the hole wall on the base plate, and the first light-shielding tape is a closed structure surrounding the first through hole.

4. (canceled)

5. The backlight module according to claim 1, further comprising:
a hole wall arranged around the first through hole and connected to an edge of the base plate adjacent to the first through hole, wherein the light board, the diffusion plate, and the optical film are located on a side of the hole wall facing away from the first through hole;
a camera embedded in the first through hole from a side of the base plate facing away from the light board, wherein the camera comprises a light-incident surface and a fixed surface arranged opposite to each other, the light-incident surface is arranged facing away from the base plate;
a control board fixedly connected to the fixed surface, comprising at least one of: a device area, a blank area and a hole area, wherein components on a side of the control board close to the fixed surface are all located in the device area, a second through hole penetrating through the control board is provided in the hole area; and
a fixing structure disposed on a side of the base plate close to the control board, comprising at least one of: a first boss, a protruding first screw hole, and a protruding first stud;
wherein the first boss is configured for adhesive fixation with the blank area, the first screw hole is configured for fixation with the second through hole via a screw, and the first stud is configured for fixation with the second through hole via a nut.

6. The backlight module according to claim 1, wherein the light board comprises:
a substrate;
a plurality of light-emitting devices spaced apart and located on a side of the substrate facing away from the base plate;
a driving device located on a side of the substrate close to the base plate; and
a reflective structure disposed on the side of the substrate facing away from the base plate and located around the light-emitting devices, the reflective structure is configured to reflect light incident from the diffusion plate back to the diffusion plate;
wherein the reflective structure comprises at least one of: reflective oil, a reflective sheet, a reflector cup, and a reflective housing;
wherein a surface of the base plate close to the light board is provided with at least one of a first groove and a thermal conductive adhesive, wherein the first groove is configured to partially or completely penetrate the base plate, and form an avoidance space for the driving device, an insulating tape is attached to a surface of the first groove close to the driving device; the thermal conductive adhesive is configured to adhere the light board to the base plate.

7. (canceled)

8. The backlight module according to claim 1, wherein the light board comprises a plurality of light-emitting devices arranged in a periodic pattern, a gap exists between the light board and the diffusion plate, the gap is proportional to an arrangement period of the light-emitting devices, with a proportional coefficient greater than or equal to 0.3 and less than or equal to 1.2.

9. The backlight module according to claim 1, further comprising:
a side plate connected to an edge of the base plate facing away from the first through hole and located on a periphery of the light board, the diffusion plate, and the optical film, wherein the side plate comprises a first side plate; and
a first frame body arranged on a side of the first side plate facing away from the first through hole, wherein a surface of the first side plate facing away from the first through hole comprises a covered area and an exposed area, the covered area is covered by the first frame body, the first frame body is adhesively fixed to the covered area, a second groove is provided in the exposed area, and a groove wall of the second groove comprises a surface of the first frame body close to the exposed area.

10. The backlight module according to claim 1, further comprising:
a side plate connected to an edge of the base plate facing away from the first through hole and located on a periphery of the light board, the diffusion plate, and the optical film, wherein the side plate comprises a second side plate;
a second frame body arranged on a side of the second side plate facing away from the first through hole, wherein the second frame body is snap-fitted to the second side plate; and
a first rubber pad located on a side of the second frame body facing away from the second side plate, wherein the first rubber pad comprises a hollowed-out structure a central area of the first rubber pad.

11. The backlight module according to claim 1, wherein an edge of the diffusion plate is provided with a first lug, and the backlight module further comprises:
a side plate connected to an edge of the base plate facing away from the first through hole and located on a periphery of the light board, the diffusion plate, and the optical film, wherein a surface of the side plate close to the first through hole is provided with a third groove, the third groove is configured to position the first lug;
at least one second rubber pad disposed between the side plate and the diffusion plate, located on at least three sides of the diffusion plate, wherein the second rubber pad and the diffusion plate are in an interference fit; and
a first adhesive layer adhered between the diffusion plate and the side plate.

12. The backlight module according to claim 1, wherein an edge of the optical film is provided with a first notch and a second lug, the first notch and the second lug are arranged on opposite edges of the optical film respectively, and the backlight module further comprises:
a side plate connected to an edge of the base plate facing away from the first through hole and located on a periphery of the light board, the diffusion plate, and the optical film, wherein a surface of the side plate close to the first through hole is provided with a second boss and a fourth groove, the second boss is configured to position the first notch, and the fourth groove is configured to position the second lug; and
a second adhesive layer comprising a plurality of adhesive portions, wherein the plurality of adhesive portions are adhered between different optical films and the side plate.

13. The backlight module according to claim 1, further comprising:
a privacy screen protector located on a side of the optical film facing away from the diffusion plate, wherein an orthographic projection of the privacy screen protector on the diffusion plate partially covers the diffusion plate, and an orthographic projection of the privacy screen protector on the base plate does not overlap with an orthographic projection of the first through hole on the base plate;
wherein an edge of the privacy screen protector is provided with a second notch and a third lug, the second notch and the third lug are located on two adjacent edges of the optical film respectively; and the backlight module further comprises:
a side plate connected to an edge of the base plate facing away from the first through hole and located on a periphery of the light board, the diffusion plate, and the optical film, wherein a surface of the side plate close to the first through hole is provided with a third boss and a fifth groove, the third boss is configured to position the second notch, and the fifth groove is configured to position the third lug:
a third frame body arranged on a side of the side plate and the privacy screen protector facing away from the base plate, third frame body comprises a privacy frame body and a non-privacy frame body, wherein the privacy frame body is adjacent to the privacy screen protector;
a third adhesive layer adhered between the privacy screen protector and the privacy frame body; and
a second light-shielding tape adhered to a surface of the non-privacy frame body close to the optical film.

14. (canceled)

15. A display device, comprising:
a display panel comprising an active display area; and
the backlight module according to claim 1, located on a side of the display panel facing away from a display surface and configured to provide a backlight source to the display panel;
wherein the active display area comprises a plurality of sub-display areas, and the display device further comprises:
a privacy panel disposed between the display panel and the backlight module, wherein the privacy panel comprises a privacy area, and the privacy area is provided with a driving structure and functional particles, the driving structure is configured to establish an electric field for driving the functional particles to move, allowing a target sub-display area to be in a privacy state or a sharing state, the target sub-display area comprises one or more of the sub-display areas.

16. (canceled)

17. The display device according to claim 15, further comprising a plurality of alignment mark groups spaced apart, each alignment mark group comprises:
a first alignment mark located in a border area on the display panel, the border area being located on at least one side of the active display area; and
a second alignment mark located on the privacy panel, wherein an orthographic projection of the second alignment mark on the display panel at least partially overlaps with the first alignment mark.

18. The display device according to claim 15, further comprising:
a first chip-on-film with a first end bonded to the display panel and a second end bent to a side of the backlight module facing away from the display panel;
a second chip-on-film with a first end bonded to the privacy panel and a second end bent to the side of the backlight module facing away from the display panel, wherein the first chip-on-film and the second chip-on-film are arranged near opposite edges of the display device, respectively;
a first drive chip connected to the first chip-on-film and located on a side of the first chip-on-film close to the backlight module; and
a second drive chip connected to the second chip-on-film and located on a side of the second chip-on-film close to the backlight module;
wherein an electromagnetic shielding tape is attached to a side of the first chip-on-film facing away from the first drive chip and a side of the second chip-on-film facing away from the second drive chip.

19. (canceled)

20. The display device according to claim 15, further comprising:
a first chip-on-film with a first end bonded to the display panel and a second end bent to a side of the backlight module facing away from the display panel;
a second chip-on-film with a first end bonded to the privacy panel and a second end bent to the side of the backlight module facing away from the display panel, wherein the first chip-on-film and the second chip-on-film are arranged near opposite edges of the display device, respectively;
a display circuit board connected to the second end of the first chip-on-film and arranged on a side of the backlight module facing away from the display panel, wherein the display circuit board comprises a first display circuit board, a second display circuit board, and a first flexible circuit board connecting the first display circuit board and the second display circuit board, wherein an electromagnetic shielding tape is attached to a side of the first flexible circuit board facing away from the backlight module; and
a privacy circuit board connected to the second end of the second chip-on-film and arranged on the side of the backlight module facing away from the display panel, wherein the privacy circuit board comprises a first privacy circuit board, a second privacy circuit board, and a second flexible circuit board connecting the first privacy circuit board and the second privacy circuit board, wherein an electromagnetic shielding tape is attached to a side of the second flexible circuit board facing away from the backlight module.

21. The display device according to claim 20, wherein the display circuit board is disposed close to the first chip-on-film, and the privacy circuit board is disposed close to the second chip-on-film;
in a normal direction of the display panel, the display circuit board and the privacy circuit board partially overlap, and a gap exists between the display circuit board and the privacy circuit board.

22. The display device according to claim 20, further comprising:
a raising structure disposed on a side of the backlight module close to the display circuit board, configured to raise the display circuit board in the normal direction of the display panel;
the raising structure comprises at least one of: a third rubber pad, a protruding second screw hole, and a protruding second stud, wherein the third rubber pad is adhesively fixed to the backlight module and the display circuit board, the second screw hole is configured for fixation with the display circuit board via a screw, and the second stud is configured for fixation with the display circuit board via a nut;
wherein the privacy circuit board comprises: a first exposed metal area close to the backlight module, and a second exposed metal area facing away from the backlight module, the first exposed metal area is connected to the backlight module via a conductive double-sided tape, the second exposed metal area is disposed near an edge of the privacy circuit board, and the second exposed metal area is connected to the backlight module via a single-sided conductive tape;
the display circuit board comprises:
a third through hole for the screw or stud to pass through, wherein a hole wall of the third through hole comprises a third exposed metal area; and
a fourth exposed metal area facing away from the backlight module, disposed near an edge of the display circuit board, wherein the fourth exposed metal area is connected to the backlight module via a single-sided conductive tape.

23. (canceled)

24. The display device according to claim 20, wherein the active display area comprises a first display partition and a second display partition, the first display circuit board is configured to drive the first display partition, and the second display circuit board is configured to drive the second display partition;
the light board comprises a first light board and a second light board spliced together, the first light board is configured to provide a light source for the first display partition, and the second light board is configured to provide a light source for the second display partition;
wherein the first light board is connected to the first display circuit board, and the second light board is connected to the second display circuit board.

25. The display device according to claim 15, wherein the active display area comprises a first sub-display area, and the display panel further comprises: a first light-transmitting area, and a first light-shielding area arranged on at least one side of the first light-transmitting area, the first sub-display area is arranged on at least one side of the first light-shielding area;
wherein an orthographic projection of the first through hole on the display panel at least partially overlaps with the first light-transmitting area.

26. The display device according to claim 15, wherein the active display area comprises a second sub-display area, and the display device further comprises:
a cover plate disposed close to a light-emitting surface of the display panel; and
vibration exciters located on a side of the cover plate close to the display panel, symmetrically disposed on opposite sides of the second sub-display area and near edges of the cover plate;
wherein the backlight module further comprises:
a side plate connected to an edge of the base plate facing away from the first through hole and located on a periphery of the light board, the diffusion plate, and the optical film;
wherein the display device further comprises:
a first chip-on-film bonded to the display panel;
a second chip-on-film bonded to the privacy panel; and
an adhesive structure disposed between the side plate and the cover plate, comprising at least one of:
a first double-sided tape located between adjacent first chips-on-film;
a second double-sided tape located between adjacent second chips-on-film, disposed on a side of the second sub-display area facing away from the first double-sided tape, and symmetrically arranged with the first double-sided tape on opposite sides of the second sub-display area;
a single-sided foam tape with its adhesive side facing the side plate, located between two adjacent second double-sided tapes;
a structural adhesive located between the first double-sided tape, the second double-sided tape, and the single-sided foam tape, with the same thickness as the first double-sided tape and the second double-sided tape; and
a plurality of mutually separated fourth bosses located on a surface of the side plate close to the cover plate, configured to limit a height between the cover plate and the side plate, wherein a single-sided tape is attached to a surface of the fourth bosses close to the cover plate.

27-29. (canceled)
